(19) United States
(12) Patent Application Publication
(10) Pub. No.: US 2022/0354008 A1
(43) Pub. Date: Nov. 3, 2022

(54) PROTECTIVE STRUCTURE FOR INPUT AND OUTPUT PORTS

(71) Applicant: TAI-SHENG HAN, New Taipei (TW)

(72) Inventor: TAI-SHENG HAN, New Taipei (TW)

(73) Assignee: EVGA CORPORATION, New Taipei (TW)

(21) Appl. No.: 17/397,880

(22) Filed: Aug. 9, 2021

(30) Foreign Application Priority Data
Apr. 28, 2021 (TW) 110204770

(51) Int. Cl. H05K 5/03; H05K 5/02; H01R 13/52

(52) U.S. Cl. CPC H05K 5/03; H05K 5/0221; H01R 13/5213

(57) ABSTRACT

A protective structure for input and output ports at least comprises a shell having a top, a first side wall and a second side wall, inside the first side wall is provided with two first side convex ribs, a first limiting groove and a first fixing hole, the second side wall is provided with two second side convex ribs, a second limiting groove and a second fixing hole; and an outer cover with a side formed with a first side guide plate assembled in the first limiting groove and provided with a first side assembling hole communicating with the first fixing hole, another side of the outer cover is formed with a second side guide plate assembled in the second limiting groove and provided with a second side assembling hole communicating with the second fixing hole. Two locking fixtures are used to lock the shell with the outer cover.

### BACKGROUND OF THE INVENTION

### Field of Invention

The invention relates a protective structure, and more particularly to a protective structure for input and output ports that can be quickly positioned and assembled to save assembly time, reduce material costs, and improve production efficiency.

### Related Art

With the continuous development of technology, the functions of electronic products are constantly improving, and the use of computers is relatively important. Computer motherboards are connected with various electronic products mainly through input and output ports, such as USB connection port, audio input/output connection port, HDMI connection port, etc. In order to protect and fix the connection ports, corresponding protective covers or fixtures are usually provided to cover the input and output ports, and the protective covers or fixtures are mainly covered and locked on the back of the motherboard or the shell. The existing protective structures on the market are usually designed with multiple assembly surfaces to be locked on different objects to be fixed by using multiple locking elements, resulting in requiring to switch to different assembly surfaces for locking the protective structure, which will cause difficulty in assembly and high assembly material costs, and the dimensional tolerances of forming the multiple locking holes corresponding to the multiple different assembly surfaces are not easy to control, which leads to inconvenience in assembly and skew after assembly.

Therefore, the inventor of the invention and relevant manufacturers engaged in this industry are eager to research and make improvement to solve the above-mentioned problems and drawbacks in the prior art.

### SUMMARY OF THE INVENTION

Therefore, in order to effectively solve the above-mentioned problems, a main object of the invention is to provide a protective structure for input and output ports that can be quickly positioned and assembled to save assembly time, reduce material costs, and improve production efficiency.

In order to achieve the above-mentioned object, the invention provides a protective structure for input and output ports at least comprising a shell, the shell has a top, a first side wall and a second side wall, inside the first side wall is provided with two first side convex ribs, a first limiting groove formed between the first side convex ribs, and a first fixing hole formed in the first limiting groove of the first side wall, and the second side wall is provided with two second side convex ribs, a second limiting groove formed between the second side convex ribs, and a second fixing hole formed in the second limiting groove of the second side wall; and an outer cover, the outer cover is assembled on a rear side of the shell, a side of the outer cover is formed with a first side guide plate assembled between the first side convex ribs and correspondingly accommodated in the first limiting groove, and the first side guide plate is provided with a first side assembling hole communicating with the first fixing hole, and another side of the outer cover is formed with a second side guide plate assembled between the second side convex ribs and correspondingly accommodated in the second limiting groove, and the second side guide plate is provided with a second side assembling hole communicating with the second fixing hole, and a plurality of through holes are formed on the outer cover.

According to one embodiment of the invention, wherein the shell is further provided with a first locking fixture that passes through the first fixing hole and the first side assembling hole and fixes the first side guide plate and the first side wall.

According to one embodiment of the invention, wherein the shell is further provided with a second locking fixture that passes through the second fixing hole and the second side assembling hole and fixes the second side guide plate and the second side wall.

According to one embodiment of the invention, wherein a top side wall is formed on an inner side of the top.

According to one embodiment of the invention, wherein a front guide plate extends forward from a top end of the outer cover, the front guide plate extends forward with an extending portion, and the extending portion and the top side wall are assembled and limited with each other.

According to one embodiment of the invention, wherein at least one side baffle extends outward from a side of the outer cover, and the side baffle is attached to the rear side of the shell.

According to one embodiment of the invention, wherein the through holes are provided for assembling at least one connection port.

### BRIEF DESCRIPTION OF THE DRAWINGS

FIG. 1 is a perspective combinational view of a protective structure for input and output ports of the invention;

FIG. 2 is a perspective exploded view of the protective structure for input and output ports of the invention;

FIG. 3 is a perspective exploded view of the protective structure for input and output ports of the invention viewed from another angle;

FIG. 4 is a perspective combinational view of the protective structure for input and output ports of the invention viewed from another angle;

FIG. 5 is a first implementation diagram of the protective structure for input and output ports of the invention; and

FIG. 6 is a second implementation diagram of the protective structure for input and output ports of the invention.

### DETAILED DESCRIPTION OF THE INVENTION

The above-mentioned object of the invention and its structural and functional features will be described based on the preferred embodiment with reference to the attached drawings.

In the following, for the formation and technical content related to a protective structure for input and output ports in the invention, various applicable examples are exemplified and explained in detail with reference to the attached drawings; however, the invention is of course not limited to the enumerated embodiment, drawings, or detailed descriptions.

Furthermore, those who are familiar with this technology should also understand that the enumerated embodiment and attached drawings are only for reference and explanation, and are not used to limit the invention; other modifications or alterations that can be easily implemented based on the detailed descriptions of the invention are also deemed to be within the scope without departing from the spirit or intention thereof as defined by the appended claims and their legal equivalents.

Furthermore, the directional terms mentioned in the following embodiment, for example: “above”, “below”, “left”, “right”, “front”, “rear”, etc., are only referring to the directions of the attached drawings. Therefore, the directional terms are used to illustrate rather than limit the invention. In addition, in the following embodiment, the same or similar elements will be labeled with the same or similar numerals.

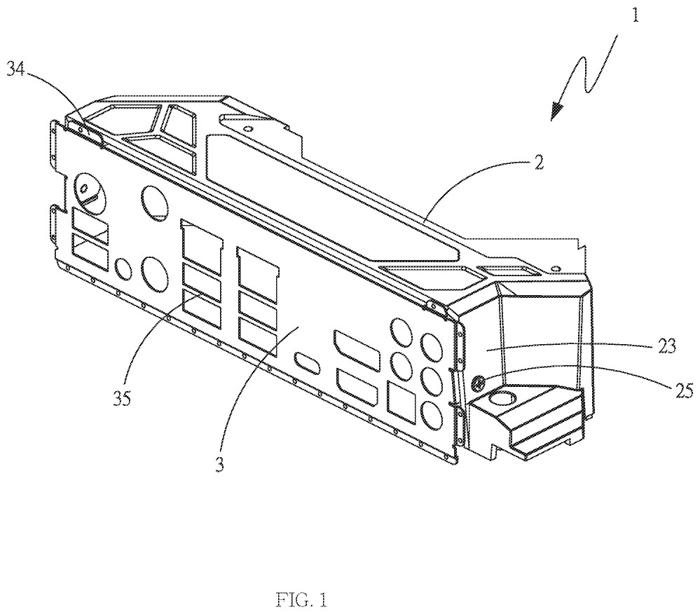

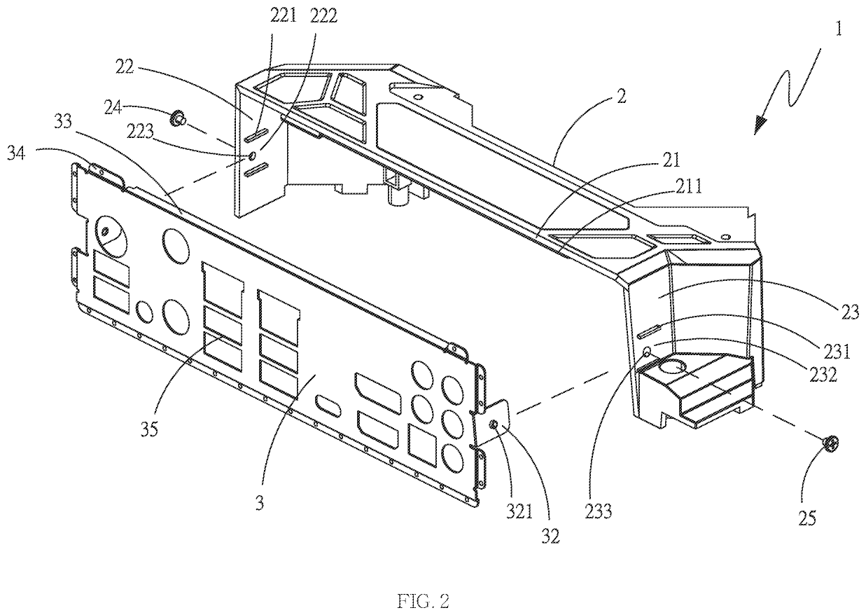

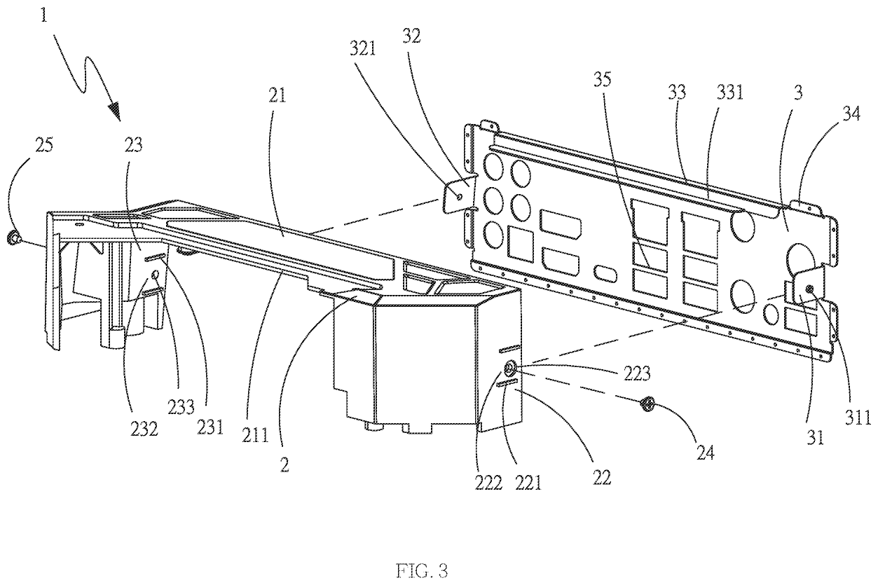

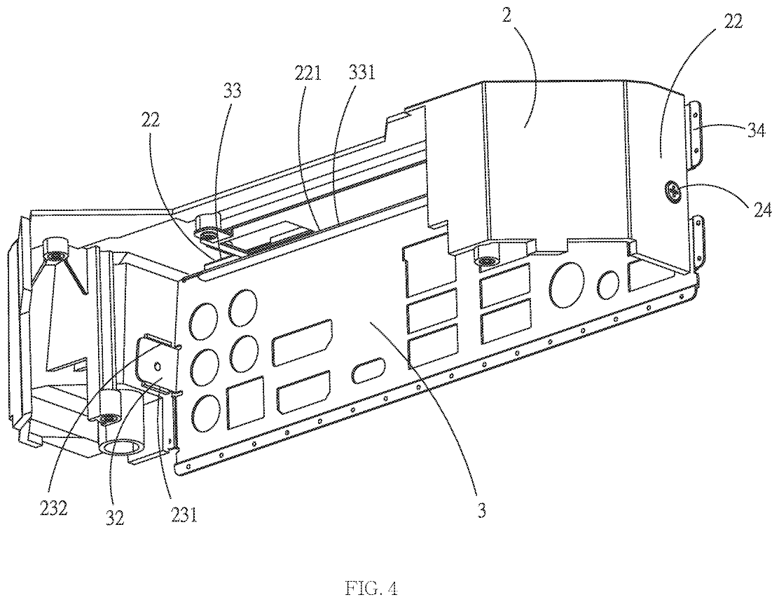

Please refer to FIGS. 1 to 4 respectively for a perspective combinational view of a protective structure for input and output ports of the invention; a perspective exploded view of the protective structure for input and output ports of the invention; a perspective exploded view of the protective structure for input and output ports of the invention viewed from another angle; and a perspective combinational view of the protective structure for input and output ports of the invention viewed from another angle. It can be clearly seen from the figures that a protective structure 1 for input and output ports comprises a shell 2 and an outer cover 3.

Wherein the shell 2 has a top 21, a top side wall 211 is formed on an inner side of the top 21, and a first side wall 22 and a second side wall 23 are respectively formed at two sides of the shell 2. A top end of the first side wall 22 extends from the top 21 and is disposed perpendicular to the top 21, two parallelly disposed first side convex ribs 221 are formed on the first side wall 22, a first limiting groove 222 is formed between the two first side convex ribs 221 of the first side wall 22, and a first fixing hole 223 is formed in the first limiting groove 222 of the first side wall 22. A top end of the second side wall 23 extends from the top 21 and is disposed perpendicular to the top 21, two parallelly disposed second side convex ribs 231 are formed on the second side wall 23, a second limiting groove 232 is formed between the two second side convex ribs 231 of the second side wall 23, and a second fixing hole 233 is formed in the second limiting groove 232 of the second side wall 23.

Wherein the outer cover 3 is assembled on a rear side of the shell 2, the outer cover 3 is formed with a first side guide plate 31 on a side corresponding to the first side wall 22, the first side guide plate 31 extends forward from a side of the outer cover 3 and is disposed perpendicular to the outer cover 3, and a first side assembling hole 311 is formed on the first side guide plate 31 to communicate with the first fixing hole 223. The outer cover 3 is formed with a second side guide plate 32 on a side corresponding to the second side wall 23, the second side guide plate 32 extends forward from a side of the outer cover 3 and is disposed perpendicular to the outer cover 3, and a second side assembling hole 321 is formed on the second side guide plate 32 to communicate with the second fixing hole 233. The outer cover 3 has a front guide plate 33 extending toward the top 21, the front guide plate 33 is limited with the inner side of the top 21, the front guide plate 33 extends forward to form an extending portion 331 in an L shape, the extending portion 331 is assembled and limited with the top side wall 211, and the outer cover 3 is capable of increasing an overall structural strength through the L-shaped extending portion 331. In addition, at least one side baffle 34 extends outward from a side of the outer cover 3, the side baffle 34 is attached to the rear side of the shell 2, and a plurality of through holes 35 are formed on the outer cover 3.

In addition, the shell 2 is further provided with a first locking fixture 24 passing through the first fixing hole 223 and the first side assembling hole 311 and fixing the first side guide plate 31 and the first side wall 22, and the shell 2 is further provided with a second locking fixture 25 passing through the second fixing hole 233 and the second side assembling hole 321 and fixing the second side guide plate 32 and the second side wall 23.

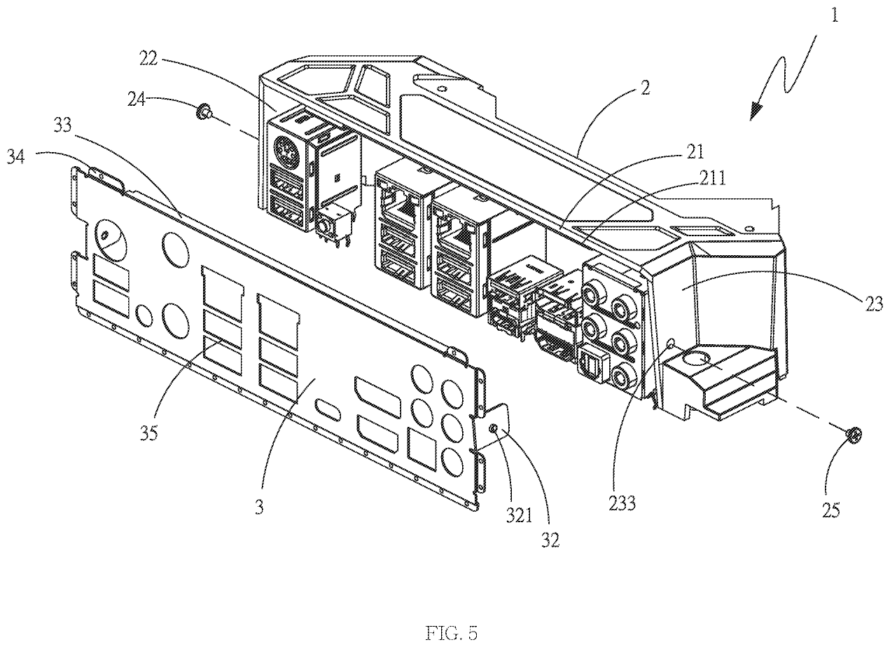

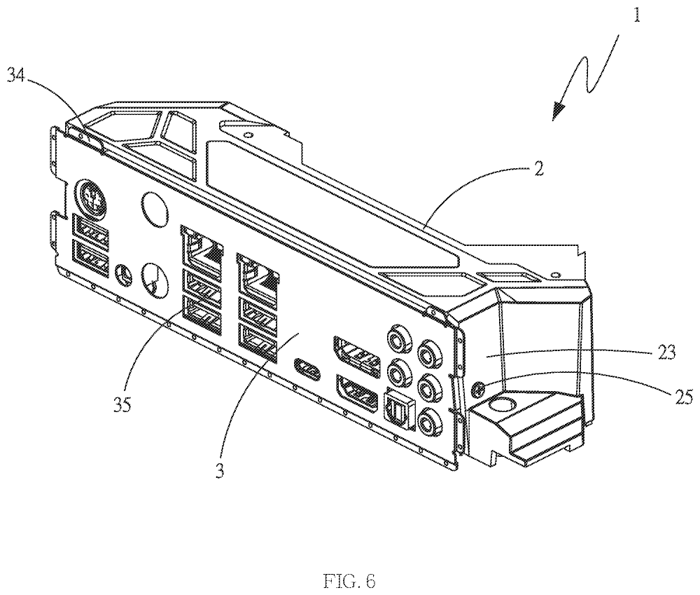

Please refer to the aforementioned drawings and FIGS. 5 and 6 respectively for a first implementation diagram and a second implementation diagram of the protective structure for input and output ports of the invention. Wherein when the protective structure 1 for input and output ports is assembled on a motherboard, the shell 2 is hooded on a connection port on the motherboard and locked, and then the outer cover 3 is assembled toward a direction of the shell 2, so that two sides of the first side guide plate 31 are attached to the first side convex ribs 221 and limited between the first side convex ribs 221, and disposed toward a direction of the first limiting groove 222 until the first fixing hole 223 communicates with the first side assembling hole 311. Correspondingly, two sides of the second side guide plate 32 are attached to the second side convex ribs 231 and limited between the second side convex ribs 231, and disposed toward a direction of the second limiting groove 232 until the second fixing hole 233 communicates with the second side assembling hole 321. When the outer cover 3 is assembled toward a direction of the shell 2, the outer cover 3 can be attached to the shell 2 through the side baffle 34, and the front guide plate 33 extends toward a direction of the top 21 and is attached to the inner side of the top 21, and the L-shaped extending portion 331 is completely attached to a corner of a wall surface of the top side wall 211, so that the outer cover 3 and the shell 2 can be completely limited with each other through the front guide plate 33 and the extending portion 331, and also capable of preventing the outer cover 3 from being displaced and misplaced due to squeezing, and further increasing a structural strength between the outer cover 3 and the shell 2. After the first fixing hole 223 communicates with the first side assembling hole 311, and the second fixing hole 233 communicates with the second side assembling hole 321, the first locking fixture 24 is then used to pass through the first fixing hole 223 and the first side assembling hole 311 to fix the first side guide plate 31 and the first side wall 22. The second locking fixture 25 passes through the second fixing hole 233 and the second side assembling hole 321 to fix the second side guide plate 32 and the second side wall 23, and the connection port passes through the through hole 35 and is limited on the outer cover 3. Thereby, after the shell 2 and the outer cover 3 of the protective structure 1 for input and output ports are quickly limited and assembled with each other, the two locking fixtures 24, 25 can be used to lock the shell 2 with the outer cover 3 in order to achieve efficacies of quick positioning and assembly to save assembly time, reduce material costs, and improve production efficiency.

It is to be understood that the above description is only the preferred embodiment of the present invention and is not used to limit the present invention, and changes in accordance with the concepts of the present invention may be made without departing from the spirit of the present invention, for example, the equivalent effects produced by various transformations, variations, modifications and applications made to the configurations or arrangements shall still fall within the scope covered by the appended claims of the present invention.

What is claimed is:

1. A protective structure for input and output ports comprising:
a shell, the shell having a top, a first side wall and a second side wall, inside the first side wall being provided with two first side convex ribs, a first limiting groove formed between the first side convex ribs, and a first fixing hole formed in the first limiting groove of the first side wall, the second side wall being provided with two second side convex ribs, a second limiting groove formed between the second side convex ribs, and a second fixing hole formed in the second limiting groove of the second side wall; and
an outer cover, the outer cover being assembled on a rear side of the shell, a side of the outer cover being formed with a first side guide plate assembled between the first side convex ribs and correspondingly accommodated in the first limiting groove, the first side guide plate being provided with a first side assembling hole communicating with the first fixing hole, another side of the outer cover being formed with a second side guide plate assembled between the second side convex ribs and correspondingly accommodated in the second limiting groove, the second side guide plate being provided with a second side assembling hole communicating with the second fixing hole, and a plurality of through holes being formed on the outer cover.

2. The protective structure for input and output ports as claimed in claim 1, wherein the shell is further provided with a first locking fixture that passes through the first fixing hole and the first side assembling hole and fixes the first side guide plate and the first side wall.

3. The protective structure for input and output ports as claimed in claim 1, wherein the shell is further provided with a second locking fixture that passes through the second fixing hole and the second side assembling hole and fixes the second side guide plate and the second side wall.

4. The protective structure for input and output ports as claimed in claim 1, wherein a top side wall is formed on an inner side of the top.

5. The protective structure for input and output ports as claimed in claim 4, wherein a front guide plate extends forward from a top end of the outer cover, the front guide plate extends forward with an extending portion, and the extending portion and the top side wall are assembled and limited with each other.

6. The protective structure for input and output ports as claimed in claim 1, wherein at least one side baffle extends outward from a side of the outer cover, and the side baffle is attached to the rear side of the shell.

7. The protective structure for input and output ports as claimed in claim 1, wherein the through hole is provided for assembling at least one connection port.
